(19) United States
(12) Patent Application Publication
(10) Pub. No.: US 2006/0267201 A1
(43) Pub. Date: Nov. 30, 2006

(54) Technique for forming copper-containing lines embedded in a low-k dielectric by providing a stiffening layer

(76) Inventors: Peter Huebler, Coswig (DE); Frank Koschinsky, Radebeul (DE); Frank Feustel, Dresden (DE)

Correspondence Address: WILLIAMS, MORGAN & AMERSON, 10333 RICHMOND, SUITE 1100, HOUSTON, TX, 77042, US

(21) Appl. No.: 11/295,756

(22) Filed: Dec. 7, 2005

(30) Foreign Application Priority Data
May 31, 2005 (DE) 10 2005 024 912.4

(51) Int. Cl. H01L 23/52; H01L 21/4763

(52) U.S. Cl. 257/758; 438/638; 438/652; 438/687; 438/639; 257/762

(57) ABSTRACT

By providing a stiffening layer at three sidewalls of a trench to be filled with a copper-containing metal, the reduced thermomechanical confinement of a low-k material may be compensated for, at least to a certain degree, thereby reducing electromigration effects and hence increasing lifetime of sophisticated semiconductor devices having metallization layers including low-k dielectric materials in combination with copper-based metal lines.

### BACKGROUND OF THE INVENTION

1. Field of the Invention

Generally, the present invention relates to the formation of microstructures, such as advanced integrated circuits, and, more particularly, to the formation of conductive structures, such as copper-based interconnect lines, and techniques to reduce their electromigration during operating and stress conditions.

2. Description of the Related Art

In the fabrication of modern microstructures, such as integrated circuits, there is a continuous drive to steadily reduce the feature sizes of microstructure elements, thereby enhancing the functionality of these structures. For instance, in modern integrated circuits, minimum feature sizes, such as the channel length of field effect transistors, have reached the deep sub-micron range, thereby increasing performance of these circuits in terms of speed and/or power consumption. As the size of individual circuit elements is reduced with every new circuit generation, thereby improving, for example, the switching speed of the transistor elements, the available floor space for interconnect lines electrically connecting the individual circuit elements is also decreased. Consequently, the dimensions of these interconnect lines also have to be reduced to compensate for a reduced amount of available floor space and for an increased number of circuit elements provided per unit die area as typically the number of interconnections required increases more rapidly than the number of circuit elements. Thus, usually a plurality of stacked “wiring” layers, also referred to as metallization layers, are provided, wherein individual metal lines of one metallization layer are connected to individual metal lines of an overlying or underlying metallization layer by so-called vias. Despite of the provision of a plurality of metallization layers, reduced dimensions of the interconnect lines are necessary to comply with the enormous complexity of, for instance, modern CPUs, memory chips, ASICs (application specific ICs) and the like. The reduced cross-sectional area of the interconnect structures, possibly in combination with an increase of the static power consumption of extremely scaled transistor elements, may result in considerable current densities in the metal lines.

Advanced integrated circuits, including transistor elements having a critical dimension of 0.13 μm and even less, may therefore require significantly increased current densities of up to several kA per cm² in the individual interconnect structures, despite the provision of a relatively large number of metallization layers, owing to the significant number of circuit elements per unit area. Operating the interconnect structures at elevated current densities, however, may entail a plurality of problems related to stress-induced line degradation, which may finally lead to a premature failure of the integrated circuit. One prominent phenomenon in this respect is the current-induced material transportation in metal lines and vias, also referred to as “electromigration,” which may lead to the formation of voids within and hillocks next to the metal interconnect, thereby resulting in reduced performance and reliability or complete failure of the device. For instance, aluminum lines embedded into silicon dioxide and/or silicon nitride are frequently used as metal for metallization layers, wherein, as explained above, advanced integrated circuits having critical dimensions of 0.18 μm or less may require significantly reduced cross-sectional areas of the metal lines and, thus, increased current densities, which may render aluminum less attractive for the formation of metallization layers.

Consequently, aluminum is being replaced by copper and copper alloys, a material with significantly lower resistivity and improved resistance to electromigration even at considerably higher current densities compared to aluminum. The introduction of copper into the fabrication of microstructures and integrated circuits comes along with a plurality of severe problems residing in copper's characteristic to readily diffuse in silicon dioxide and a plurality of low-k dielectric materials. To provide the necessary adhesion and to avoid the undesired diffusion of copper atoms into sensitive device regions, it is therefore usually necessary to provide a barrier layer between the copper and the dielectric material in which the copper-based interconnect structures are embedded. Although silicon nitride is a dielectric material that effectively prevents the diffusion of copper atoms, selecting silicon nitride as an interlayer dielectric material is less then desirable, since silicon nitride exhibits a moderately high permittivity, thereby increasing the parasitic capacitances of neighboring copper lines, which may result in non-tolerable signal propagation delays. Hence, a thin conductive barrier layer that also imparts the required mechanical stability to the copper is formed to separate the bulk copper from the surrounding dielectric material, and only a thin silicon nitride or silicon carbide or silicon carbon nitride layer in the form of a capping layer is frequently used in copper-based metallization layers. Currently, tantalum, titanium, tungsten and their compounds, with nitrogen and silicon and the like, are preferred candidates for a conductive barrier layer, wherein the barrier layer may comprise two or more sub-layers of different composition to meet the requirements in terms of diffusion suppressing and adhesion properties.

Another characteristic of copper significantly distinguishing it from aluminum is the fact that copper may not readily be deposited in larger amounts by chemical and physical vapor deposition techniques, in addition to the fact that copper may not be efficiently patterned by anisotropic dry etch processes, thereby requiring a process strategy that is commonly referred to as the damascene or inlaid technique. In the damascene process, first a dielectric layer is formed which is then patterned to include trenches and vias which are subsequently filled with copper, wherein, as previously noted, prior to filling in the copper, a conductive barrier layer is formed on the sidewalls of the trenches and vias. The deposition of the bulk copper material into the trenches and vias is usually accomplished by wet chemical deposition processes, such as electroplating and electroless plating, thereby requiring the reliable filling of vias with an aspect ratio of 5 and more with a diameter of 0.3 μm or even less in combination with trenches having a width ranging from 0.1 μm to several μm. Electrochemical deposition processes for copper are well established in the field of electronic circuit board fabrication. However, the void-free filling of high aspect ratio vias is an extremely complex and challenging task, wherein the characteristics of the finally obtained copper-based interconnect structure significantly depend on process parameters, materials and geometry of the structure of interest. Since the geometry of interconnect structures is substantially determined by the design requirements and may, therefore, not be significantly altered for a given microstructure, it is of great importance to estimate and control the impact of materials, such as conductive and non-conductive barrier layers, of the copper microstructure and their mutual interaction on the characteristics of the interconnect structure to insure both high yield and the required product reliability. In particular, it is important to identify, monitor and reduce degradation and failure mechanisms in interconnect structures for various configurations to maintain device reliability for every new device generation or technology node.

Accordingly, a great deal of effort has been invested in investigating the degradation of copper interconnects, especially in combination with low-k dielectric materials having a relative permittivity of 3.1 or even less, in order to find new materials and process strategies for forming copper-based lines and vias with a low overall permittivity. Although the exact mechanism of electromigration in copper lines is still not quite fully understood, it turns out that voids positioned in and on sidewalls and especially at interfaces to neighboring materials may have a significant impact on the finally achieved performance and reliability of the interconnects.

One failure mechanism, which is believed to significantly contribute to a premature device failure, is the electromigration-induced material transport particularly along an interface formed between the copper and a dielectric capping layer acting as an etch stop layer during the formation of vias in the interlayer dielectric. Frequently used materials are, for example, silicon nitride and silicon carbon nitride, which exhibit a moderately high etch selectivity to typically employed interlayer dielectrics, such as a plurality of low-k dielectric materials, and also suppress the diffusion of copper onto the interlayer dielectric. Recent research results seem to indicate, however, that the interface formed between the copper and the etch stop layer is a major diffusion path for material transport during operation of the metal interconnect.

Another important factor of significant electromigration in copper-based lines embedded into a low-k dielectric material seems to reside in the specific thermomechanical characteristics of the low-k dielectric, in addition to the specific material characteristics of the copper arising from the specific damascene manufacturing regime. Lee et al., “Electromigration reliability of dual-damascene Cu/porous methylsilsesquioxane low k interconnects,” Appl. Phys. Lett., 82:2032, 2003, reports on the degradation of life time owing to excessive electromigration caused by a reduced back stress in copper lines due to a reduced thermomechanical confinement of the copper lines in the low-k dielectric. Thus, the test results indicate an increased electromigration of copper lines embedded in a low-k material compared to an SiO₂ dielectric, which is attributed to the increased softness and expansion and reduced heat conductivity of the low-k material relative to SiO₂.

In view of the above-described problems, there exists a need for a technique that allows the reduction of electromigration in copper-based interconnect structures without unduly increasing production costs and affecting the electrical conductivity of the metal interconnect.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present invention is directed to a technique that enables the formation of metal lines in metallization layers including a low-k dielectric material, wherein the confinement of the metal line in the low-k dielectric material is enhanced by reinforcing the stiffness of major interface portions between the low-k dielectric material and the metal. Thus, the metal line may build up an enhanced back stress upon operation and other stress conditions that may otherwise lead to stress-induced material transport, such as electromigration, so that the occurrence of significant material transport may be reduced compared to conventional low-k metallization interconnect structures without an additional stiffening mechanism.

According to one illustrative embodiment of the present invention, a method comprises forming an opening, which is in one illustrative embodiment a trench, in a low-k dielectric layer and modifying surface areas of the dielectric material of the low-k dielectric layer at a bottom and the sidewalls of the opening to increase an elastic modulus of the modified surface area. Moreover, the opening is filled with a copper-containing metal to form an interconnect line of a metallization layer.

In accordance with another illustrative embodiment of the present invention, a semiconductor device comprises a metallization layer comprising a low-k dielectric material and a copper-containing metal line formed therein. The metal line is confined, at least at the side-walls, by a stiffening layer having an elastic modulus that is higher than both an elastic modulus of the copper-containing metal line and an elastic modulus of the low-k dielectric material.

### BRIEF DESCRIPTION OF THE DRAWINGS

The invention may be understood by reference to the following description taken in conjunction with the accompanying drawings, in which like reference numerals identify like elements, and in which:

FIGS. 1a-1g schematically show cross-sectional views of a semiconductor device including a copper-based interconnect line with a stiffening layer, i.e., a modified portion formed on corresponding sidewalls and a bottom surface of a trench formed in a low-k dielectric material in accordance with illustrative embodiments of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present invention is based on the concept that the thermomechanical confinement of copper-based metal lines in a low-k dielectric may be enhanced by modifying surface portions of a trench or a via to endow surface portions of the trench or via, i.e., interfaces between the core of the metal line or via, with an enhanced stiffness. This means, the elastic modulus of the modified surface portion is higher than that of the non-modified low-k dielectric material, thereby enabling the metal line or the via to produce a higher back stress that may then be counteracted by the reinforced surface and interface portions of the trench or via, which may finally result in an enhanced electromigration behavior of the metal line or via compared to conventional devices without modified, i.e., stiffened, interface portions.

In this respect, a low-k dielectric material is to be understood as a dielectric having a relative permittivity that is less than approximately 3.1 and hence exhibits a significantly smaller permittivity than, for instance, well-established “conventional” dielectrics, such as silicon dioxide, silicon nitride and the like. However, as previously explained, the reduced relative permittivity is typically associated with a reduced elastic modulus, thereby rendering low-k dielectric materials typically softer and less heat-conductive compared to the conventional interlayer dielectrics, such as silicon dioxide. For example, in a typical silicon dioxide layer formed from TEOS at moderately low temperatures, as is typically encountered in sophisticated semiconductor applications for the formation of an interlayer dielectric on the basis of copper lines, the elastic modulus may be approximately 70 GPa, while the corresponding elastic modulus for a typical low-k material may range from approximately 3-7 GPa. In the present invention, it is therefore contemplated to modify exposed surface portions of a trench, and in some embodiments, additionally exposed surface portions of vias, to receive a higher elastic modulus, thereby stiffening these surface portions without unduly compromising the overall relative permittivity of the metallization layer. With reference to the accompanying drawings, further illustrative embodiments of the present invention will now be described in more detail.

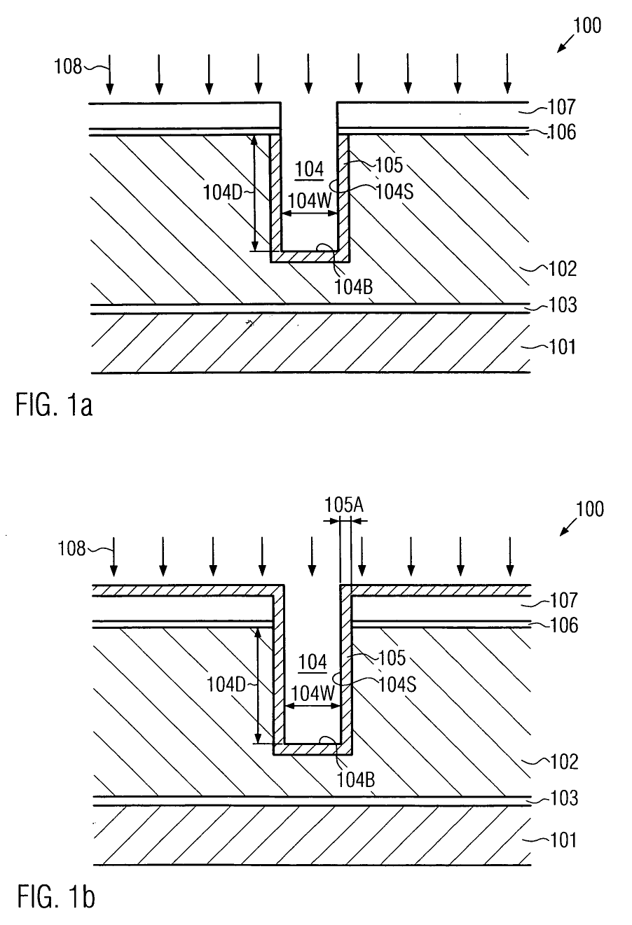

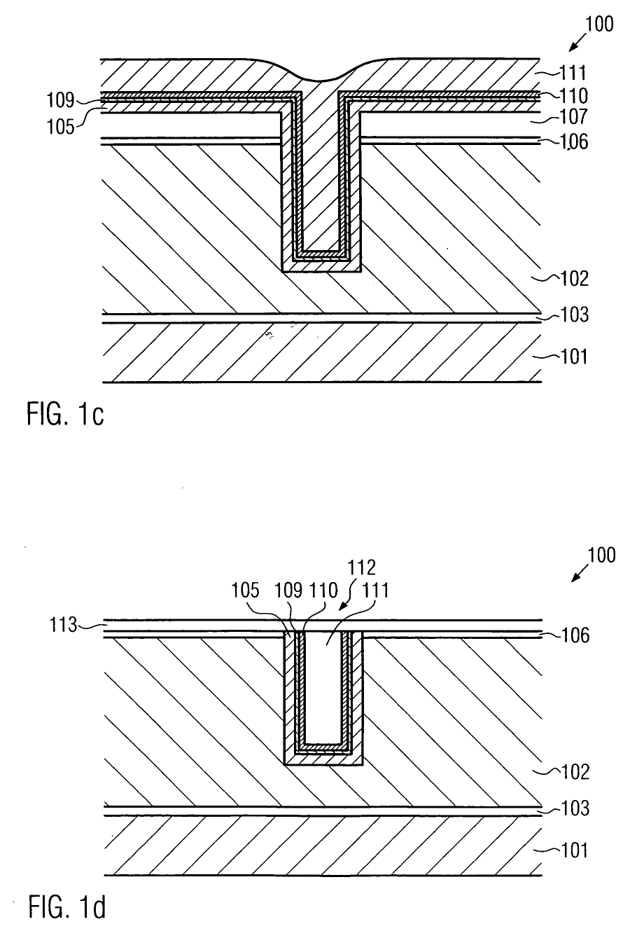

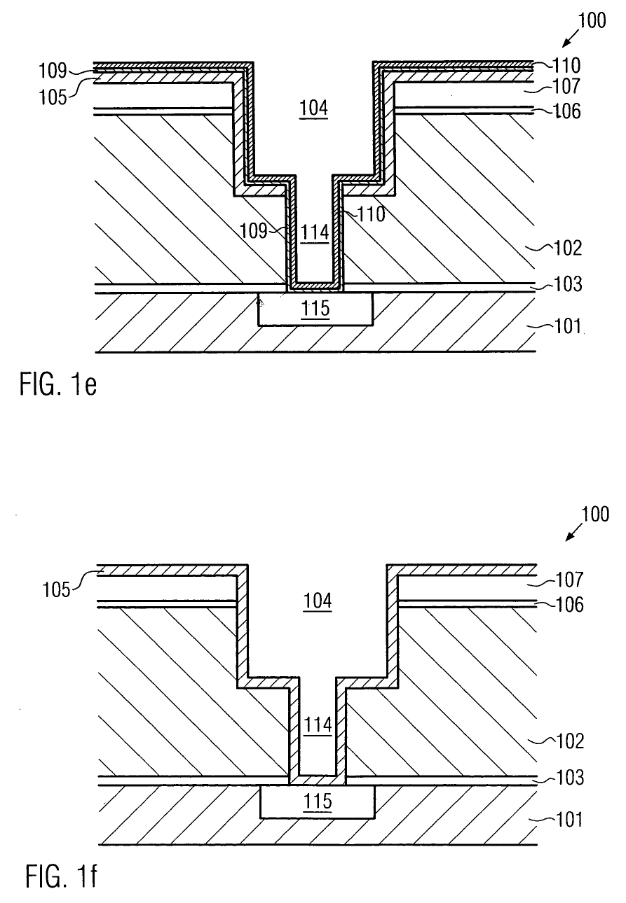

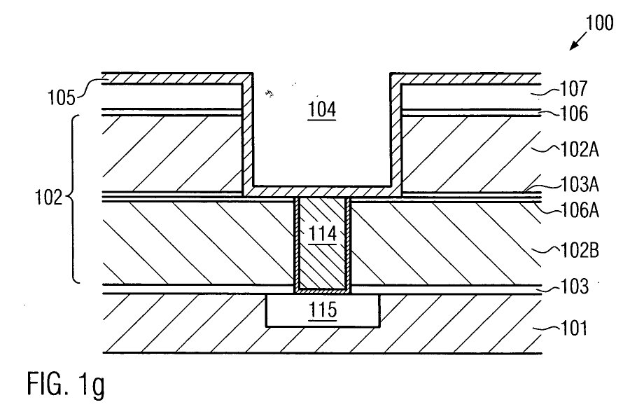

FIG. 1a schematically illustrates a cross-sectional view of a semiconductor device 100 during a moderately advanced manufacturing stage. The semiconductor device 100 comprises a substrate 101, which may represent any substrate that is appropriate for forming semiconductor devices thereon. For instance, the substrate 101 may be a bulk semiconductor substrate, an insulating substrate having formed thereon a crystalline semiconductor region, such as a crystalline silicon region, a silicon/germanium region, or any other III-V semiconductor compounds or II-VI compounds, and the like. Typically, the substrate 101 may represent a carrier having formed thereon a large number of circuit elements, such as transistors, capacitors, resistors and the like, as are required for integrated circuits. These circuit elements may be electrically connected in accordance with a specific circuit design by means of one or more metallization layers, wherein, for convenience, the formation of a single metallization layer including a single metal line will be described herein. It may, however, be readily appreciated that the concept of enhancing the thermomechanical confinement of a copper-based metallization line in a low-k dielectric may be applied to any complex device configuration including a plurality of metallization layers and a large number of interconnect lines and vias. Moreover, although the present invention is particularly advantageous for extremely scaled semiconductor devices since here, as previously discussed, moderately high current densities are usually encountered during the operation of the device, the present invention is also readily applicable and advantageous for moderately scaled devices, due to a significantly enhanced reliability and lifetime that may be obtained by further reducing the electromigration or other stress-induced material transport phenomena, which may typically be encountered in combination with metal lines embedded into a low-k dielectric material.

The semiconductor device 100 may further comprise an etch stop layer 103, for instance formed of silicon nitride, silicon carbon nitride, silicon carbide and the like, which may be used as a capping layer for a metal region (not shown) and as an etch stop in forming vias (not shown) to an underlying circuit element or to an underlying metallization layer (not shown), as will be described in more detail later on with reference to FIGS. 1e-1g. A dielectric layer 102, also referred to as an interlayer dielectric, is formed above the etch stop layer 103 and is comprised of any appropriate material, wherein at least a portion of the dielectric layer 102 is comprised of a low-k dielectric material. Some exemplary low-k dielectric materials include, without being exhaustive, hydrogen-containing silicon oxycarbide (SiCOH), having a permittivity in the range of approximately 2.8-3.1, porous SiCOH, BD2™, BD3™, formed in accordance with process techniques from Applied Materials, DEMS™, OMCCS™, Tomcat™, formed in accordance with process techniques from Dow Corning, SILK, porous SILK, MSQ, HSQ, and the like. In some embodiments, substantially the entire dielectric layer 102 may be formed from a low-k dielectric material, whereas, in other embodiments, an upper portion thereof, in which a trench 104 is formed, may be comprised of the low-k dielectric material. The layer 102 comprising the trench 104, which is to be filled with metal, is also referred to as a metallization layer. The trench 104 has dimensions, i.e., a width 104w, a depth 104d and a length (the dimension perpendicular to the drawing plane of FIG. 1a) in accordance with design requirements. For instance, the width 104w and the depth 104d determine, in combination with the specified material to be filled in the trench 104, its conductivity per unit length. In one illustrative embodiment, the trench 104 may be bordered by modified surface areas 105, which may also be referred to as stiffening layer 105, since the stiffening layer 105 is configured to exhibit a higher elastic modulus compared to the adjacent low-k dielectric material of the layer 102. For example, the elastic modulus of the stiffening layer 105 may be higher than approximately 10 GPa, and, in some embodiments, the elastic modulus may range from approximately 20-100 GPa and even more. Thus, the stiffening layer 105 provides enhanced confinement of a metal material to be filled into the trench 104 by endowing sidewalls 104s and the bottom face 104b with an enhanced rigidity or stiffness. It should be appreciated that the bottom surface 104b may not be completely covered by the stiffening layer 105, when any vias (not shown) may have to be formed that connect to the trench 104 and to any underlying contact region, as will be described in more detail later on.

In illustrative embodiments, the semiconductor device 100 may further comprise a capping layer 106, which may be comprised of silicon dioxide, silicon carbide and the like, and which may be provided to impart an enhanced mechanical strength to the low-k dielectric layer 102. Furthermore, the semiconductor device 100 may comprise an anti-reflective coating (ARC) layer 107, comprised of, for instance, silicon oxynitride, silicon carbide, silicon oxycarbide and the like, wherein a thickness and optical characteristics of the ARC layer 107 may be designed to act as an anti-reflective coating during a photolithography process for forming the trench 104. In other cases, the layer 107, possibly in combination with the layer 106, may act as an ARC layer, a hard mask and a capping layer during the formation of the trench 104.

A typical process flow for forming the semiconductor device 100, as shown in FIG. 1a, may comprise the following processes. After any well-established process techniques for forming any circuit elements and microstructural elements in and on the substrate 101, the etch stop layer 103, if required, may be formed by well-established deposition techniques, such as plasma enhanced chemical vapor deposition (PECVD) and the like. Thereafter, the dielectric layer 102 may be formed in accordance with device and process requirements, wherein spin-on techniques may be used for applying the low-k dielectric material when provided in the form of liquid polymer material, or wherein appropriate deposition techniques, such as chemical vapor deposition and the like, may be used. In one illustrative embodiment, the dielectric layer 102 may be substantially comprised of SiCOH, which may be formed by PECVD on the basis of 3MS (trimethylsilane), 4MS and oxygen with well-approved process recipes. In other embodiments, other materials, such as the low-k materials previously described, in combination or individually, may be used in forming the dielectric layer 102. Thereafter, the capping layer 106 may be formed by deposition or treatment of the layer 102, for instance by exposing the layer 102 to a specified reactive ambient so as to modify the surface of the layer 102 in order to form the layer 106 having enhanced mechanical stability. In other embodiments, an appropriate material layer, such as silicon dioxide, may be deposited on the basis of TEOS or silane, depending on process requirements.

Next, the layer 107 may be deposited on the basis of well-established PECVD recipes, followed by the application of a resist layer, which is then patterned by photolithography on the basis of well-known techniques. Thereafter, the patterned resist mask and possibly the patterned ARC layer 107 may be used as an etch mask for an anisotropic etch process to form the trench 104 in the dielectric layer 102. Corresponding anisotropic etch recipes for etching through the low-k dielectric material of the layer 102 are well established in the art.

Next, the semiconductor device 100 may be subjected to a surface treatment, indicated as 108, during which radiation and/or heat and/or a reactive ambient may be applied to the exposed trench 104 to form the stiffening layer 105 by surface modification. In one illustrative embodiment, the dielectric layer 102 may be substantially comprised of SiCOH and the surface treatment 108 may include a treatment in an oxidizing plasma ambient, thereby forming substantially silicon dioxide on exposed surface areas of the dielectric layer 102 in order to create the stiffening layer 105, which then exhibits a significantly higher elastic modulus compared to the remaining low-k dielectric material of the layer 102. For example, by providing oxygen in a plasma ambient, wherein an appropriate bias power may be applied, a silicon dioxide layer having a thickness in the range of approximately 10-50 nm may be formed. In other embodiments, the surface treatment 108 may include a treatment on the basis of a plasma ambient that contains a stiffening material, which may be introduced into the exposed surface portions of the layer 102 to form the stiffening layer 105. For example, a nitridation process may be performed to incorporate nitrogen, thereby forming the stiffening layer 105. In still other embodiments, the treatment 108 may comprise the application of radiation, for instance in the form of a particle radiation or a photonic radiation, such as light radiation, to thereby modify exposed surface portions of the trench 104. In some embodiments, one or more treatment steps, i.e., treatment by a plasma ambient and treatment with heat and/or radiation, may be combined to form the stiffening layer 105. In one illustrative embodiment, a silicon dioxide layer may be formed by means of an oxygen-containing plasma ambient, wherein subsequently a heat treatment and/or a radiation treatment may be performed to densify and thus enhance the mechanical stability of the silicon dioxide layer.

In some embodiments, the treatment 108 may comprise a treatment by radiation and/or heat in a highly localized manner, wherein the heat and/or the radiation are substantially confined to the vicinity of the trench 104. For example, if a general heat treatment is considered not appropriate, since a modification of material characteristics of layer portions of the layer 102 distant from the trench 104 is not desired, the heat and/or the radiation may be applied to the trench 104 substantially without affecting the neighboring device areas. For this purpose, any radiation focusing techniques, such as optical focusing means, electric focusing means for charged particle rays, nozzles for transferring a heated medium and the like, may be used to locally treat the trench 104. It should be appreciated that, in sophisticated semiconductor devices, typically metal lines are oriented substantially parallel in a single direction and hence appropriately designed focusing means may be scanned across the substrate 101 parallel to the trench 104 for a plurality of trenches 104 so that the corresponding heat and/or radiation is highly localized during the scan process, while nevertheless providing a moderately high throughput. For example, a laser source of appropriate wavelength may be focused to produce a substantially focused radiation spot having dimensions that substantially correspond to the width 104w of the trench 104, wherein the spot may be directed at a specified trench portion and may then be scanned along the length of the trench 104. In other embodiments, the thermal and optical characteristics of the layers 107 and 106 may sufficiently prevent any pronounced modification of portions of the dielectric layer 102 so that the treatment 108 may be performed in a global manner while locally forming the stiffening layer 105.

FIG. 1b schematically shows the semiconductor device 100, wherein the surface treatment 108 may comprise, in addition or alternatively, a deposition process to form the stiffening layer 105. Thus, the stiffening layer 105 is also formed above the layer 107, wherein, in some embodiments, a further treatment by radiation and/or heat may have been performed prior to the deposition of the stiffening layer 105 and/or after the deposition of the stiffening layer 105. For example, silicon dioxide, silicon nitride or the like may be deposited and may subsequently be subjected to a further treatment to further alter the material characteristics of the layer as deposited to obtain the desired elastic modulus. In some illustrative embodiments, a thickness 105a of the stiffening layer 105 is selected to obtain, in combination with a thickness of the trench 104 after the anisotropic etch process, the desired design thickness 104w so as to comply with conductivity requirements of the material to be filled into the trench 104. Thus, when performing the photolithography for patterning the trench 104, the corresponding width and depth of the trench are selected to take into consideration the additional thickness 105a to obtain the desired width 104w and depth 104d.

In some embodiments, the stiffening layer 105 when deposited during the treatment 108 may be comprised of a non-metallic material, whereas, in other embodiments, a metallic material may be used. For instance, in one illustrative embodiment, the stiffening layer 105 may comprise tantalum, wherein the thickness 105a may range from approximately 20-50 nm, thereby providing a significantly enhanced mechanical strength compared to conventional devices, in which conductive barrier layers including tantalum are provided with a thickness of 20 nm and even less for sophisticated semiconductor devices 100 including field effect transistors having critical gate length dimensions of 100 nm or 50 nm and even less. Moreover, other metal-containing materials, such as silicides formed from tungsten, platinum and the like, may be used to form the stiffening layer 105. For this purpose, well-established process recipes may be used.

FIG. 1c schematically shows the semiconductor device 100 in a further advanced manufacturing stage. The device 100 comprises a conductive barrier layer 109, which is comprised of a material that significantly reduces copper diffusion into the stiffening layer 105 and then into the low-k dielectric material of the layer 102. For example, tantalum, tantalum nitride, titanium, titanium nitride and any combinations thereof may be used as appropriate conductive barrier layers. In some illustrative embodiments, the stiffening layer 105 may itself be comprised of a barrier material, thereby providing the potential for completely omitting the barrier layer 109 or specifically designing the characteristics of the barrier layer 109 in conformity with other requirements, such as enhanced adhesion and the like. For example, as previously described, the stiffening layer 105 may be provided by deposition and silicon nitride may be used as dielectric material, which exhibits excellent copper diffusion blocking characteristics so that the barrier layer 109 may be omitted. In still other embodiments, an interface between silicon nitride and a copper-based material may be considered as inappropriate, due to significant electromigration that may occur at this interface. Therefore, the barrier layer 109 may be provided, wherein the material composition may be selected with respect to improved resistance against electromigration. For example, a metal such as aluminum may be deposited as the barrier layer 109, wherein aluminum may form an alloy with copper, thereby significantly enhancing the resistance with respect to electromigration at a surface between the copper/aluminum alloy and silicon nitride.

Furthermore, the semiconductor device 100 may comprise a seed layer 110 formed on the conductive barrier layer 109, followed by a metal layer 111 comprising copper, wherein, in sophisticated applications, the major part of the metal layer 111 may be comprised of copper due to its low resistivity compared to other metals.

The semiconductor device 100 as shown in FIG. 1c may be formed in accordance with the following process flow. After performing further optional photolithography processes, when a dual damascene regime is used in accordance with the so-called trench first/via last approach, as will be described in more detail later on, the barrier layer 109 may be formed by any appropriate deposition technique. For example, tantalum, tantalum nitride, titanium, titanium nitride may be deposited on the basis of well-established sputter deposition techniques. Moreover, for highly sophisticated applications, atomic layer deposition (ALD) may be used to form a very thin and highly conformal barrier layer. For instance, for tantalum nitride, corresponding ALD recipes are well established in the art. In advanced applications, it may be advantageous to provide extremely thin barrier layers, while nevertheless guaranteeing a highly reliable coverage of all surface portions of the stiffening layer 105 within the trench 104 to significantly reduce mutual diffusion of material of the stiffening layer 105 into the metal layer 111, and vice versa. For example, in some embodiments, it may be advantageous to provide the stiffening layer 105 in the form of a conductive or metal-containing layer, while a direct contact with the copper in the metal layer 111 may be undesirable. Since then the stiffening layer 105 as well as the metal layer 111 may provide the electrical conductivity, wherein, typically, the conductivity of the stiffening layer 105 may significantly be less than that of the metal layer 111, a very thin barrier layer 109 is provided so as to not unduly compromise the overall conductivity while nevertheless prevent, or substantially reduce, metal interdiffusion between the layers 105 and 111.

After the formation of the barrier layer 109, if provided, the seed layer 110 may be formed by any appropriate deposition technique, such as physical vapor deposition, sputter deposition, electroless plating and the like. In some particular embodiments, the seed layer 110 may be formed of copper to promote a subsequent electroplating process for forming the metal layer 111. In other embodiments, the seed layer 110 may be formed by means of electroless plating on the basis of appropriate plating chemistries, wherein previously a catalyst material may have been deposited to initiate and promote the deposition of copper during the electroless process. For this purpose, the stiffening layer 105 and/or the barrier layer 109 may have been formed so as to include a certain amount of catalyst material, such as copper, cobalt, palladium, platinum and the like. Thus, a highly conformal seed layer with enhanced crystallinity may be formed by electroless plating, wherein the application of the catalyst may not require additional process steps. Next, the copper-containing metal layer 111 may be formed by electroplating or electroless plating on the basis of well-established recipes, wherein the layer 111 is typically provided with a certain amount of excess material so as to ensure a reliable filling of the trench 104. Next, the excess material of the layer 111 and the layers 110, 109, 105 and 107 may be removed from horizontal surface portions of the device 100 by appropriate techniques, such as electrochemical polishing and chemical mechanical polishing (CMP), wherein the layer 107 or a portion thereof may also act as a CMP stop layer.

FIG. 1d schematically shows the semiconductor device 100 after the completion of the above-described process sequence. Moreover, the device 100 comprises an etch stop layer or capping layer 113, which may be comprised of silicon nitride, silicon carbide, nitrogen-enriched silicon carbide and the like. Consequently, the device 100 comprises a copper-containing metal line 112 formed in the dielectric layer 102, wherein the metal line 112 may comprise a conductive core formed by the layer 111, the seed layer 110 and, if provided, by the barrier layer 109, wherein this conductive core is bordered at sidewalls thereof and the bottom by the stiffening layer 105, which may in some embodiments be formed, at least partially, of a conductive or metal-containing material, while in other embodiments the stiffening layer 105 is comprised of a dielectric material. The stiffening layer 105 having an elastic modulus that is higher than that of the surrounding low-k dielectric material of the layer 102 allows build up of an increased back stress in the metal line 112 during operating and stress conditions compared to a conventional device without the stiffening layer 105, in which the metal line 112 is in direct contact with the low-k material of the dielectric layer 102. Consequently, a stress-induced material transport within the metal line 112 may be reduced due to the increased back stress and therefore the time to failure of the metal line 112 may significantly be increased.

It should be appreciated that a plurality of process techniques are established in the art to form copper-based metallization layers, wherein single and dual damascene regimes are used. For example, the process flow described above with reference to FIGS. 1a-1d is in principle appropriate for any of these techniques, wherein, depending on process and device requirements, any vias may be formed with and without the stiffening layer 105, as will now be described in more detail.

FIG. 1e schematically shows the semiconductor device 100 in accordance with further illustrative embodiments, wherein the cross-sectional view is taken at a position at which a via 114 is to be formed to a lower lying conductive region 115. The region 115 may represent a metal line of a lower lying metallization layer, a contact region of a circuit element, and the like. The semiconductor device 100 as shown in FIG. 1e may be formed in accordance with the same processes as are also described with reference to FIGS. 1a and 1b. In particular, the formation of the stiffening layer 105 after the patterning of the trench 104 may be carried out as is previously described. In the embodiment shown, the stiffening layer 105 is illustrated as being formed at least by a deposition process, as is described with reference to FIG. 1b. It should be appreciated, however, that any other embodiments described with reference to FIG. 1a may also be used to form the stiffening layer 105. Thereafter, the via 114 may be formed by performing a further photolithography process in accordance with well-established trench first/via last damascene strategies. That is, after the formation of the stiffening layer 105, an appropriate ARC material, such as a polymer material, may be deposited so as to substantially planarize the surface topology of the device 100. Thereafter, photoresist may be applied and patterned in accordance with photolithography recipes. Then, the via 114 may be formed through the trench 104 and through the dielectric layer 102 wherein, as previously discussed, the lower portion of the dielectric layer 102 may not necessarily be comprised of a low-k dielectric material. Consequently, the stiffening layer 105 may not be necessary in the via 114. In other embodiments, the dielectric layer 102 may be substantially completely comprised of a low-k dielectric material wherein, however, the formation of the stiffening layer within the via 114 may not be considered appropriate. After the formation of the via 114 through the dielectric layer 102 and the etch stop layer 103, the further processing may be resumed in a similar fashion as is also described with reference to FIG. 1c. That is, the barrier layer 109 and the seed layer 110 may be formed in accordance with-established techniques and thereafter the trench 104 and the via 114 may commonly be filled with the copper-containing metal.

FIG. 1f schematically shows the semiconductor device 100, wherein the stiffening layer 105 is formed within both the trench 104 and the via 114. For this purpose, the trench 104 and the via 114 are formed in accordance with established trench first/via last or via first/trench last damascene approaches, wherein, in illustrative embodiments, the corresponding thickness of the stiffening layer 105 is taken into consideration for the design rules of the trench 104 and the via 114, as is also described with reference to FIG. 1a. After the formation of the trench 104 and the via 114, the stiffening layer 105 may be formed by deposition, wherein, in some embodiments, the deposition is performed after the opening of the etch stop layer 103 so that the stiffening layer 105 may be formed on the conductive region 115. In some embodiments, the stiffening layer 105 is thereby provided in the form of a conductive material to provide an electrical contact to the region 115. In other embodiments, an anisotropic etch process may be performed after the deposition of the stiffening layer 105 to etch through the layer 105 at the bottom of the via 114. It should be appreciated that a thickness of the stiffening layer 105 at the via bottom may significantly be less than a thickness of the layer 105 at the trench bottom due to the deposition kinetics during the formation of the layer 105. Thus, the via 114 may be opened while only reducing a thickness at the trench bottom 104. In other embodiments, the stiffening layer 105 may be formed by surface treatment without a deposition, for instance by heating the device 100 in an oxidizing ambient so as to form silicon dioxide, if the layer 102 is substantially comprised of SiCOH. Hereby, also metal oxide may form within the conductive region 115, which may then however efficiently be removed on the basis of a selective etch process prior to forming a conductive barrier layer and a seed layer, as is also described above. Moreover, in some embodiments, the etch stop layer 103 may not be completely opened during the formation of the via 114 and the residue thereof may remain during a surface treatment for forming the stiffening layer 105, wherein the remaining etch stop layer 103 may then be opened by a corresponding isotropic or anisotropic selective etch process. For instance, the etch stop layer 103 may be comprised of silicon nitride from which a significant amount may be removed during a correspondingly designed etch step after etching through the layer 102. Thereafter, a surface treatment, such as the treatment 108, may be performed to form silicon dioxide on exposed portions of the layer 102 within the trench 104 and the via 114 and thereafter the via 114 may completely be opened and the further processing may be resumed, similar to the process flow described above with reference to FIG. 1e. Thus, the via 114 may also effectively be confined by the stiffening layer 105, irrespective of whether a conductive or a dielectric stiffening layer 105 is provided, thereby also enhancing the performance of the via 114.

FIG. 1g schematically shows the semiconductor device 100 in accordance with further illustrative embodiments. In these embodiments, the via 114 may be formed first in a portion 102b of the dielectric layer 102 and may then be filled with metal, such as a copper-containing metal and a conductive barrier layer, wherein, in some embodiments, additionally a stiffening layer (not shown) may be provided, whereas, in other embodiments, as shown, the stiffening layer may be omitted. A second portion 102a of the dielectric layer is comprised of a low-k dielectric material, in which the trench 104 is formed. For this purpose, an additional etch stop layer 103a formed on a corresponding capping layer 106a, which may be provided if the layer 102b is comprised of a low-k dielectric material, is used to reliably stop the anisotropic etch process for forming the trench 104. In a subsequent process step, the etch stop layer 103a may be opened to also expose the via 114. Thereafter, the stiffening layer 105 may be formed by deposition, wherein a conductive material is used, such as tantalum, in order to establish an electric contact to the via 114. Thereafter, the further processing may be continued as is described above. In other embodiments, the mechanical characteristics of the capping layer 106a may be considered appropriate for the confinement of the bottom of the trench 104, and the stiffening layer 105 may be formed by a dielectric material, possibly by a surface treatment as described with reference to FIG. 1a. Thus, the stiffening layer 105 may substantially be formed on the sidewalls of the trench 104, when no further deposition process is involved. In still other embodiments, in addition to or alternatively, a deposition process may be performed to deposit a dielectric material to form the stiffening layer 105, as shown in FIG. 1g. Thereafter, an anisotropic etch process may be performed to remove the stiffening layer 105 from horizontal portions, and in particular from the bottom of the trench 104 to expose the via 114. Thereafter, a barrier layer and a seed layer and the bulk metal for the trench 104 may be deposited in similar processes as are described above.

As a result, the present invention provides a technique that enables an enhanced confinement of copper-based metal lines in a low-k dielectric by providing a stiffening layer that has a higher elastic modulus compared to the low-k dielectric material. Thus, during operation of the device, a stress-induced material transport may be reduced compared to conventional devices, since a copper-based metal line may create increased back stress to counteract the stress-induced material transport in the metal line. Consequently, the time to failure of the metal line confined by the stiffening layer may be increased, without unduly compromising the overall performance of the device with respect to operating speed.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming an opening in a low-k dielectric layer;
modifying surface areas of the dielectric material of said low-k dielectric layer at a bottom and sidewalls of said opening to increase an elastic modulus of said modified surface areas; and
filling said opening with a copper-containing metal to form an interconnect line of a metallization layer.

2. The method of claim 1, wherein filling said opening with a copper-containing metal comprises:
depositing a conductive barrier layer in said opening;
forming a seed layer above said barrier layer; and
depositing said copper-containing metal on said seed layer.

3. The method of claim 1, wherein modifying said surface areas comprises forming a stiffening layer by depositing a stiffening material having a higher elastic modulus compared to said low-k dielectric material.

4. The method of claim 3, wherein said stiffening material is a non-metallic material.

5. The method of claim 3, wherein said stiffening material is a metallic material.

6. The method of claim 4, wherein said stiffening material is comprised of at least one of silicon dioxide and silicon nitride.

7. The method of claim 3, further comprising determining design dimensions of said interconnect line, determining a target thickness of said stiffening layer and forming said opening according to said design dimensions and said target thickness.

8. The method of claim 3, wherein said stiffening layer comprises tantalum.

9. The method of claim 1, wherein modifying said surface areas comprises treating said surface areas by at least one of heat and radiation.

10. The method of claim 1, wherein modifying said surface areas comprises treating said surface areas in a plasma ambient containing a precursor of a stiffening material.

11. The method of claim 1, further comprising forming a via connecting to said opening and extending through said low-k dielectric layer and into an electrically conductive region.

12. The method of claim 11, wherein said via is formed prior to modifying said surface areas.

13. The method of claim 11, wherein said via is filled with a copper-containing metal prior to modifying said surface areas.

14. The method of claim 12, further comprising modifying exposed surface areas of said via to form a stiffening layer thereon.

15. The method of claim 1, wherein said opening is a trench.

16. A semiconductor device, comprising:
a metallization layer comprising a low-k dielectric material and a copper-containing metal line formed therein, said metal line being confined, at least at sidewalls, by a stiffening layer having an elastic modulus that is higher than both an elastic modulus of said copper-containing metal line and an elastic modulus of said low-k dielectric material.

17. The semiconductor device of claim 16, wherein said stiffening layer is comprised of a dielectric material.

18. The semiconductor device of claim 17, wherein said dielectric material comprises at least one of silicon dioxide and silicon nitride.

19. The semiconductor device of claim 16, wherein said stiffening layer is comprised of a metal-containing material.

20. The semiconductor device of claim 16, wherein said metal line comprises a conductive barrier layer.

21. The semiconductor device of claim 20, wherein said barrier layer comprises tantalum.

22. The semiconductor device of claim 16, further comprising a copper-containing metal filled via connecting to said metal line and extending through said low-k dielectric layer, wherein said copper-containing metal of said via comprises a conductive barrier layer that is in contact with said low-k dielectric layer.

23. The semiconductor device of claim 16, further comprising a copper-containing metal filled via connecting to said metal line and extending through said low-k dielectric layer, wherein said copper-containing metal of said via comprises a conductive barrier layer and said stiffening layer that is in contact with said low-k dielectric layer.
